(19) United States
(12) Patent Application Publication
(10) Pub. No.: US 2024/0072139 A1
(43) Pub. Date: Feb. 29, 2024

(54) SEMICONDUCTOR DEVICE AND METHOD OF MANUFACTURING SEMICONDUCTOR DEVICE

(71) Applicant: SUMITOMO ELECTRIC INDUSTRIES, LTD., Osaka (JP)

(72) Inventor: Kenta SUGAWARA, Osaka (JP)

(21) Appl. No.: 18/308,976

(22) Filed: Apr. 28, 2023

(30) Foreign Application Priority Data
Aug. 23, 2022 (JP) 2022-132699

(51) Int. Cl. H01L 29/417; H01L 29/16; H01L 29/66; H01L 29/778

(52) U.S. Cl. CPC H01L 29/41775; H01L 29/1608; H01L 29/66462; H01L 29/7786

(57) ABSTRACT

A semiconductor device includes a substrate; a semiconductor layer provided on the substrate; a source electrode and a drain electrode provided on the semiconductor layer; a first film including a first insulating film that is provided on the semiconductor layer and is located between the source electrode and the drain electrode; a gate electrode provided between the source electrode and the drain electrode; and a silicon carbide layer covering the gate electrode. The first film has an opening. The gate electrode includes a first portion that is located within the opening in a plan view, and a second portion that is connected to the first portion, is disposed on the first film, and is located closer to the drain electrode than the first portion is.

### CROSS-REFERENCE TO RELATED APPLICATIONS

This application is based on and claims priority to Japanese Patent Application No. 2022-132699, filed on Aug. 23, 2022, the entire contents of which are incorporated herein by reference.

### TECHNICAL FIELD

The present disclosure relates to a semiconductor device and a method of manufacturing the semiconductor device.

### BACKGROUND

Japanese Laid-open Patent Publication No. 2019-71339 (Patent Document 1) and Japanese Laid-open Patent Publication No. 2020-102489 (Patent Document 2) propose high electron mobility transistors (HEMTs) in which, in order to improve heat dissipation, a diamond film is provided between a head portion of a gate electrode having a T-shape in a cross-sectional view and a semiconductor layer. The head portion of the gate electrode functions as a field plate that reduces electric field concentration in the vicinity of the gate electrode.

### SUMMARY

According to the present disclosure, a semiconductor device includes a substrate; a semiconductor layer provided on the substrate; a source electrode and a drain electrode, the source electrode and the drain electrode being provided on the semiconductor layer; a first film including a first insulating film that is provided on the semiconductor layer and is located between the source electrode and the drain electrode; a gate electrode provided between the source electrode and the drain electrode; and a silicon carbide layer covering the gate electrode. The first film has an opening. The gate electrode includes a first portion that is located within the opening in a plan view, and a second portion that is connected to the first portion, is disposed on the first film, and is located closer to the drain electrode than the first portion is.

### BRIEF DESCRIPTION OF THE DRAWINGS

Other objects and further features of the present invention will be apparent from the following detailed description when read in conjunction with the accompanying drawings, in which:

FIG. 1 is a cross-sectional view of a semiconductor device according to a first embodiment;

FIG. 2 is a cross-sectional view (part 1) illustrating a method of manufacturing the semiconductor device according to the first embodiment;

FIG. 3 is a cross-sectional view (part 2) illustrating the method of manufacturing the semiconductor device according to the first embodiment;

FIG. 4 is a cross-sectional view (part 3) illustrating the method of manufacturing the semiconductor device according to the first embodiment;

FIG. 5 is a cross-sectional view (part 4) illustrating the method of manufacturing the semiconductor device according to the first embodiment;

FIG. 6 is a cross-sectional view (part 5) illustrating the method of manufacturing the semiconductor device according to the first embodiment;

FIG. 7 is a cross-sectional view (part 6) illustrating the method of manufacturing the semiconductor device according to the first embodiment;

FIG. 8 is a cross-sectional view (part 7) illustrating the method of manufacturing the semiconductor device according to the first embodiment;

FIG. 9 is a cross-sectional view illustrating the effects of the semiconductor device according to the first embodiment;

FIG. 10 is a cross-sectional view of a semiconductor device according to a second embodiment;

FIG. 11 is a cross-sectional view (part 1) illustrating a method of manufacturing the semiconductor device according to the second embodiment;

FIG. 12 is a cross-sectional view (part 2) illustrating the method of manufacturing the semiconductor device according to the second embodiment;

FIG. 13 is a cross-sectional view (part 3) illustrating the method of manufacturing the semiconductor device according to the second embodiment;

FIG. 14 is a cross-sectional view (part 4) illustrating the method of manufacturing the semiconductor device according to the second embodiment;

FIG. 15 is a cross-sectional view (part 5) illustrating the method of manufacturing the semiconductor device according to the second embodiment;

FIG. 16 is a cross-sectional view of a semiconductor device according to a third embodiment;

FIG. 17 is a cross-sectional view of a semiconductor device according to a fourth embodiment;

FIG. 18 is a cross-sectional view of a semiconductor device according to a fifth embodiment;

FIG. 19 is a cross-sectional view of a semiconductor device according to a sixth embodiment;

FIG. 20 is a cross-sectional view of a semiconductor device according to a seventh embodiment; and

FIG. 21 is a cross-sectional view of a semiconductor device according to an eighth embodiment.

### DETAILED DESCRIPTION

The thermal conductivity of diamond is higher than the thermal conductivity of silicon nitride. However, in the above-described HEMTs, if the distance between the head portion of the gate electrode and the semiconductor layer is small, the diamond film is thin, and thus sufficient heat dissipation cannot be obtained. Conversely, if the diamond film is thick, the distance between the head portion of the gate electrode and the semiconductor layer is large, and thus electric field concentration in the vicinity of the gate electrode cannot be sufficiently reduced.

According to the present disclosure, heat dissipation can be improved while reducing electric field concentration in the vicinity of a gate electrode.

### Description of Embodiments of Present Disclosure

First, embodiments of the present disclosure will be listed and described.

[1] According to one aspect of the present disclosure, a semiconductor device includes a substrate; a semiconductor layer provided on the substrate; a source electrode and a drain electrode, the source electrode and the drain electrode being provided on the semiconductor layer; a first film including a first insulating film that is provided on the semiconductor layer and is located between the source electrode and the drain electrode; a gate electrode provided between the source electrode and the drain electrode; and a silicon carbide layer covering the gate electrode. The first film has an opening. The gate electrode includes a first portion that is located within the opening in a plan view, and a second portion that is connected to the first portion, is disposed on the first film, and is located closer to the drain electrode than the first portion is.

Heat is easily generated in a region of the semiconductor layer in the vicinity of the first portion. The heat not only diffuses into the substrate but also diffuses into the source electrode and the drain electrode through the gate electrode and the silicon carbide layer. At this time, the heat can be discharged with high efficiency since the thermal resistance of the silicon carbide layer is relatively low. Further, the second portion of the gate electrode functions as a field plate. Although the first film is present between the second portion and the semiconductor layer, the first film can be thin since high thermal conductivity is not required for the first film. Therefore, electric field concentration in the vicinity of the gate electrode can be sufficiently reduced by the second portion. Accordingly, heat dissipation can be improved while reducing electric field concentration in the vicinity of the gate electrode.

[2] In [1], the semiconductor device may further include a second film that is provided between the first film and the silicon carbide layer, covers a lower surface of the silicon carbide layer, and does not contain nitrogen. In this case, mixing of nitrogen into the silicon carbide layer can be suppressed by the second film.

[3] In [2], the second film may be an aluminum oxide film or a silicon oxide film. The chemical stability of Al—O bonds constituting the aluminum oxide film and the chemical stability of Si—O bonds constituting the silicon oxide film are high. Therefore, diffusion of nitrogen is easily suppressed by the aluminum oxide film or the silicon oxide film.

[4] In [1], the first film may include a third film that is provided between the first insulating film and the silicon carbide layer, covers a lower surface of the silicon carbide layer, and does not contain nitrogen. In this case, mixing of nitrogen into the silicon carbide layer can be suppressed by the third film.

[5] In [4], the third film may be an aluminum oxide film, a silicon oxide film, a diamond film, or a diamond-like carbon film. The chemical stability of Al—O bonds constituting the aluminum oxide film, the chemical stability of Si—O bonds constituting the silicon oxide film, and the chemical stability of C—C bonds constituting the diamond film or the diamond-like carbon film are high. Therefore, diffusion of nitrogen is easily suppressed by the aluminum oxide film, the silicon oxide film, the diamond film, or the diamond-like carbon film.

[6] In any of [1] to [5], the first insulating film may be a silicon nitride film. In this case, the surface of the semiconductor layer is easily protected.

[7] In any of [1] to [6], the semiconductor device may further include a fourth film that covers an upper surface of the silicon carbide layer and does not contain nitrogen. In this case, mixing of nitrogen into the silicon carbide layer can be suppressed by the fourth film.

[8] In [7], the fourth film may be an aluminum oxide film or a silicon oxide film. The chemical stability of Al—O bonds constituting the aluminum oxide film and the chemical stability of Si—O bonds constituting the silicon oxide film are high. Therefore, diffusion of nitrogen is easily suppressed by the aluminum oxide film or the silicon oxide film.

[9] In any of [1] to [8], the silicon carbide layer may directly contact the gate electrode. In this case, heat is easily transferred from the gate electrode to the silicon carbide layer.

[10] In any of [1] to [9], the semiconductor device may further include a first metal layer including the source electrode; and a second metal layer including the drain electrode. The silicon carbide layer may directly contact at least one of the first metal layer or the second metal layer. In this case, heat is easily transferred from the silicon carbide layer to the first metal layer or the second metal layer.

[11] In [10], a distance between the gate electrode and the first metal layer may be 5 μm or less, and a distance between the gate electrode and the second metal layer may be 5 μm or less. In this case, excellent heat dissipation is easily obtained.

[12] In any of [1] to [11], a distance between the semiconductor layer and the second portion may be 100 nm or less. In this case, electric field concentration in the vicinity of the gate electrode is easily reduced by the second portion.

[13] According to another aspect of the present disclosure, a semiconductor device includes a substrate; a semiconductor layer provided on the substrate; a source electrode and a drain electrode, the source electrode and the drain electrode being provided on the semiconductor layer; a first film including a silicon nitride film that is provided on the semiconductor layer and is located between the source electrode and the drain electrode; a gate electrode provided between the source electrode and the drain electrode; a silicon carbide layer covering the gate electrode; a second film that is provided between the first film and the silicon carbide layer, covers a lower surface of the silicon carbide layer, and does not contain nitrogen; a first metal layer including the source electrode; and a second metal layer including the drain electrode. The first film has an opening. The gate electrode includes a first portion that is located within the opening in a plan view, and a second portion that is connected to the first portion, is disposed on the first film, and is located closer to the drain electrode than the first portion is. The second film is an aluminum oxide film or a silicon oxide film. The silicon carbide layer directly contacts at least one of the first metal layer or the second metal layer. A distance between the semiconductor layer and the second portion is 100 nm or less. In this case, heat dissipation can be improved while reducing electric field concentration in the vicinity of the gate electrode.

[14] According to yet another aspect of the present disclosure, a method of manufacturing a semiconductor device includes forming a semiconductor layer on a substrate; forming a source electrode and a drain electrode on the semiconductor layer; forming a first film including a first insulating film on the semiconductor layer and between the source electrode and the drain electrode; forming an opening in the first film; forming a gate electrode including a first portion and a second portion, the first portion being located within the opening in a plan view, and the second portion being disposed on the first film and being located closer to the drain electrode than the first portion is; and forming a silicon carbide layer so as to cover the gate electrode. With this configuration, heat dissipation can be improved while reducing electric field concentration in the vicinity of the gate electrode.

### Details of Embodiments of Present Disclosure

In the following, the embodiments of the present disclosure will be described in detail; however, the present disclosure is not limited thereto. In the specification and the drawings, elements having substantially the same functional configurations are denoted by the same reference numerals, and the description thereof may be omitted.

### First Embodiment

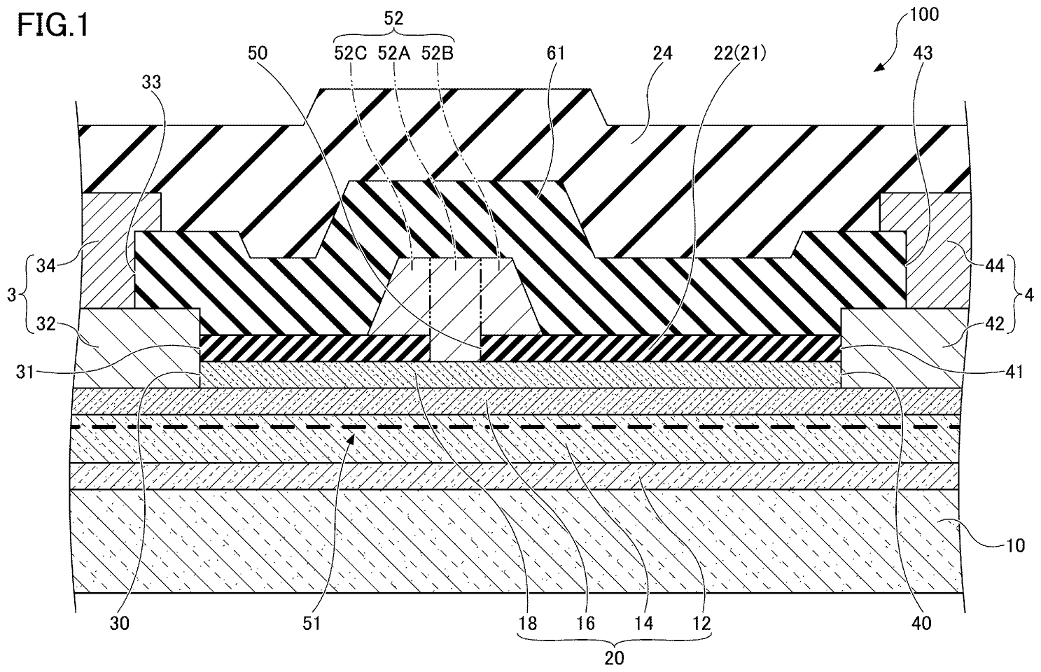

A first embodiment will be described. The first embodiment relates to a semiconductor device including a gallium-nitride-based high electron mobility transistor (GaN-HEMI) whose main constituent material is a nitride semiconductor. FIG. 1 is a cross-sectional view of a semiconductor device according to the first embodiment.

As illustrated in FIG. 1, a semiconductor device 100 according to the first embodiment includes a substrate 10 and a stacked structure 20 of a plurality of semiconductor layers that are formed on the substrate 10. The substrate 10 is a silicon carbide (SiC) substrate having an upper surface with a (0001) plane orientation, for example. A buffer layer 12 is an aluminum nitride (AlN) layer having a thickness of, for example, 5 nm or more and 100 nm or less. An electron transit layer 14 is an undoped gallium nitride (GaN) layer having a thickness of, for example, approximately 1000 nm. An electron supply layer 16 is an n-type aluminum gallium nitride (AlGaN) layer having a thickness of, for example, approximately 20 nm. A capping layer 18 is an n-type GaN layer having a thickness of, for example, approximately 5 nm. An n-type impurity used in the present embodiment is, for example, silicon (Si) or germanium (Ge). The stacking direction of the buffer layer 12, the electron transit layer 14, the electron supply layer 16, and the capping layer 18 is, for example, the [0001]-direction. A two-dimensional electron gas (2DEG) 51 is present near the upper surface of the electron transit layer 14. The stacked structure 20 is an example of a semiconductor layer.

A silicon nitride (SiN) film 22 is formed on the capping layer 18. Openings 31 and 41 are formed in the SiN film 22, and openings 30 and 40 are formed in the capping layer 18. The opening 31 leads to the opening 30, and the opening 41 leads to the opening 40. The thickness of the SiN film 22 is, for example, 100 nm or less. The SiN film 22 is an example of a first film 21, and is an example of a first insulating film.

A source electrode 32 is formed in the openings 30 and 31, and a drain electrode 42 is formed in the openings 40 and 41. The upper surfaces of the source electrode 32 and the drain electrode 42 may be located above the upper surface of the SiN film 22. The source electrode 32 and the drain electrode 42 both includes, for example, a titanium (Ti) film and an aluminum (Al) film. For 13 example, the thickness of the Ti film is 30 nm, and the thickness of the Al film is 300 nm. A tantalum (Ta) film may be used instead of the Ti film. The source electrode 32 and the drain electrode 42 are in ohmic contact with the 2DEG 51.

An opening 50 is formed in the SiN film 22. The capping layer 18 is exposed from the opening 50. For example, the opening 50 is closer to the source electrode 32 than to the drain electrode 42. A gate electrode 52 is formed between the source electrode 32 and the drain electrode 42. The gate electrode 52 includes a first portion 52A, a second portion 52B, and a third portion 52C. The first portion 52A is located within the opening 50 in a plan view. The second portion 52B is connected to the first portion 52A, is disposed on the SiN film 22, and is located closer to the drain electrode 42 than the first portion 52A is. The third portion 52C is connected to the first portion 52A, is disposed on the SiN film 22, and is located closer to the source electrode 32 than the first portion 52A is. The first portion 52A directly contacts the capping layer 18 through the opening 50. The gate electrode 52 has a T-shape in a cross-sectional view. The gate electrode 52 includes, for example, a nickel (Ni) film and a gold (Au) film.

A silicon carbide (SiC) layer 61 covering the gate electrode 52 is formed on the SiN film 22, the source electrode 32, and the drain electrode 42. Openings 33 and 43 are formed in the SiC layer 61. The source electrode 32 is exposed from the opening 33, and the drain electrode 42 is exposed from the opening 43. The thickness of the SiC layer is, for example, 200 nm or more and 1000 nm or less.

Source wiring 34 is formed in the opening 33, and drain wiring 44 is formed in the opening 43. A portion of the source wiring 34 and a portion of the drain wiring 44 may be located on the SiC layer 61. Each of the source wiring 34 and the drain wiring 44 includes at least one selected from the group consisting of tungsten (W), gold (Au), aluminum (Al), copper (Cu), and titanium (Ti). The first metal layer 3 includes the source electrode 32 and the source wiring 34, and the second metal layer 4 includes the drain electrode 42 and the drain wiring 44.

A passivation film 24 covering the SiC layer 61, the source wiring 34, and the drain wiring 44 is formed. The passivation film 24 is, for example, a SiN film.

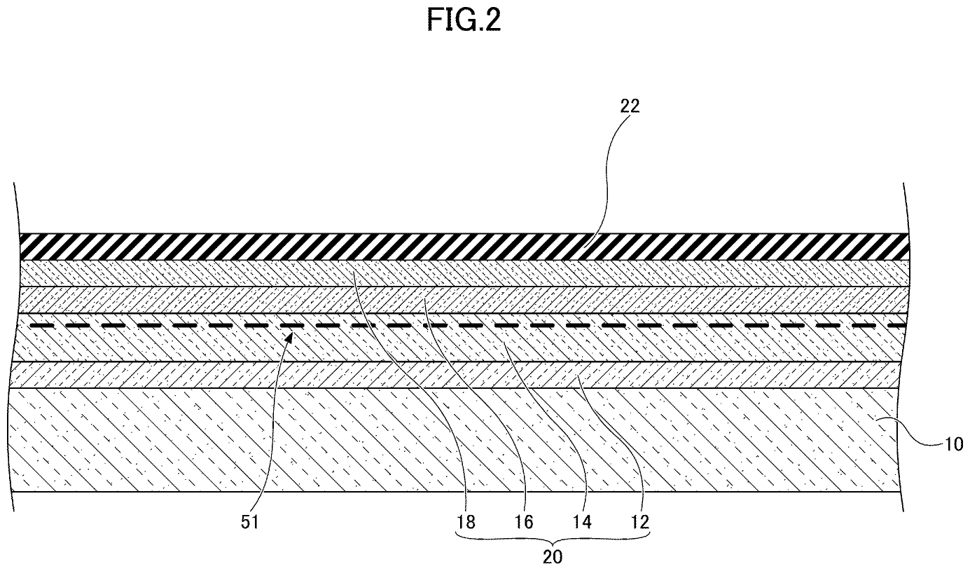

Next, a method of manufacturing the semiconductor device 100 according to the first embodiment will be described. FIG. 2 through FIG. 8 are cross-sectional views illustrating the method of manufacturing the semiconductor device 100 according to the first embodiment.

First, as illustrated in FIG. 2, the buffer layer 12, the electron transit layer 14, the electron supply layer 16, and the capping layer 18 are formed on the substrate 10. The buffer layer 12, the electron transit layer 14, the electron supply layer 16, and the capping layer 18 can be formed by, for example, a metal organic chemical vapor deposition (MOCVD) method. Next, the SiN film 22 is formed on the capping layer 18. The SiN film 22 can be formed by, for example, a chemical vapor deposition (CVD) method.

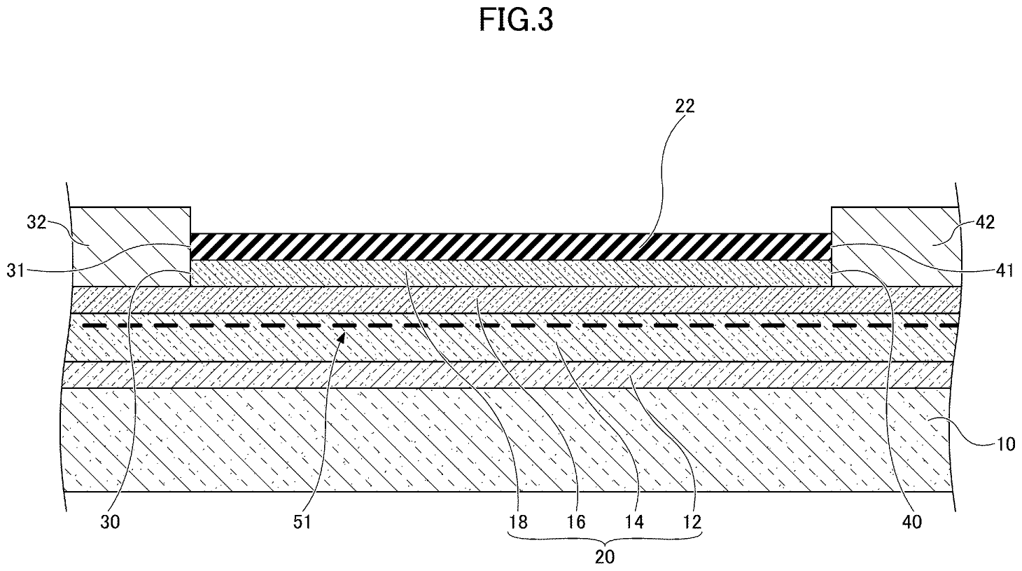

Next, as illustrated in FIG. 3, the openings 31 and 41 are formed in the SiN film 22, and the openings 30 and 40 are formed in the capping layer 18. The openings 31 and 41 can be formed by reactive ion etching (RIE) using a reactive gas including, for example, fluorine (F). The openings and 40 can be formed by RIE using a reactive gas including, for example, chlorine (Cl).

Next, the source electrode 32 is formed in the openings 30 and 31, and the drain electrode 42 is formed in the openings 40 and 41. The source electrode 32 and the drain electrode 42 can be formed by, for example, vapor deposition, lift-off, or alloying heat treatment.

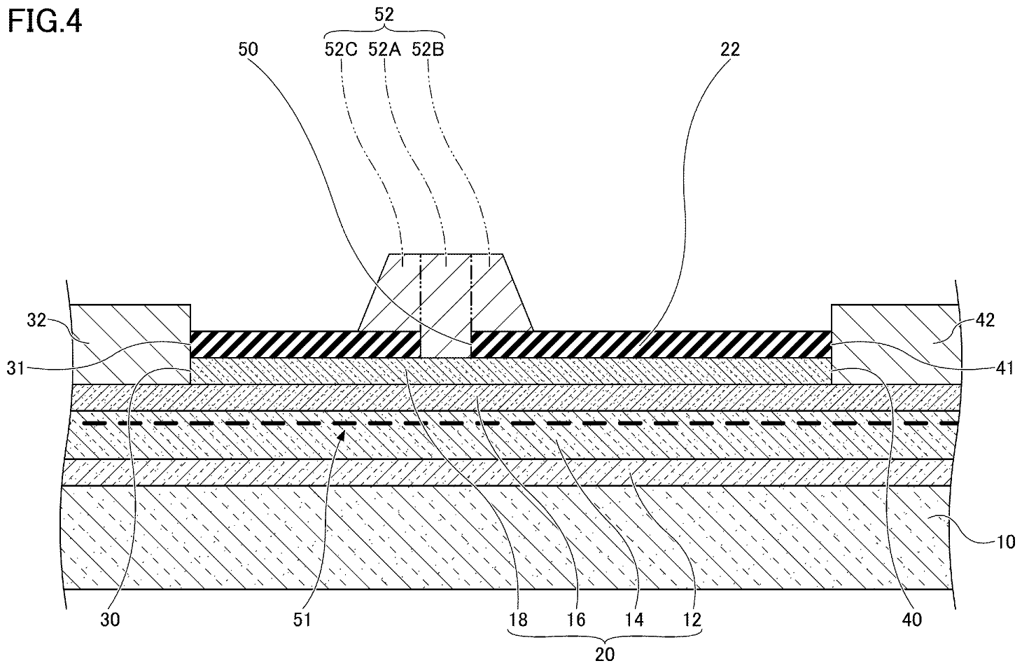

Next, as illustrated in FIG. 4, the opening 50 is formed in the SiN film 22. The opening 50 can be formed by RIE using a reactive gas including, for example, F. Next, the gate electrode 52 including the first portion 52A, the second portion 52B, and the third portion 52C is formed. The gate electrode 52 can be formed by, for example, vapor deposition or lift-off.

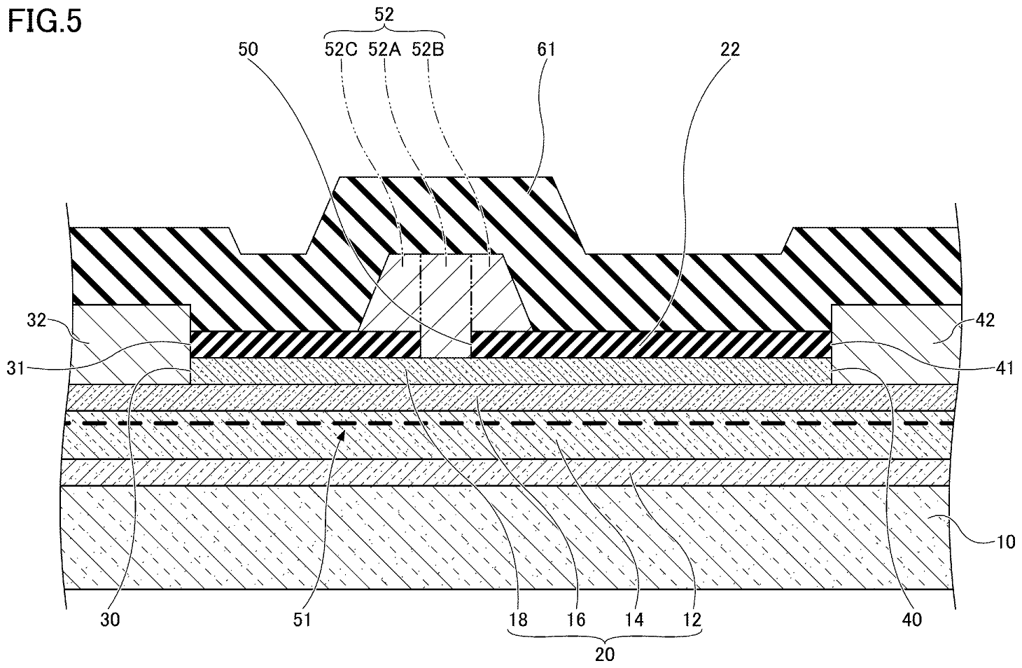

Next, as illustrated in FIG. 5, the SiC layer 61 is formed so as to cover the gate electrode 52, the SiN film 22, the source electrode 32, and the drain electrode 42. The SiC layer 61 can be formed by, for example, a plasma CVD method. When the SiC layer 61 is formed, a SiₓC_{y}H_{z}-based material such as tetramethylsilane (Si(CH₃)₄) is used as a source gas, and a noble gas such as hydrogen (H₂) or argon (Ar) is used as a dilution gas. Note that it is preferable not to use a substance including nitrogen such as hexamethyldisilazane ((CH₃)₃SiNHSi(CH₃)₃). The temperature of the substrate 10 when the SiC layer 61 is formed is preferably 400° C. or lower in order to suppress changes in the characteristics of the gate electrode 52 due to alloying or the like.

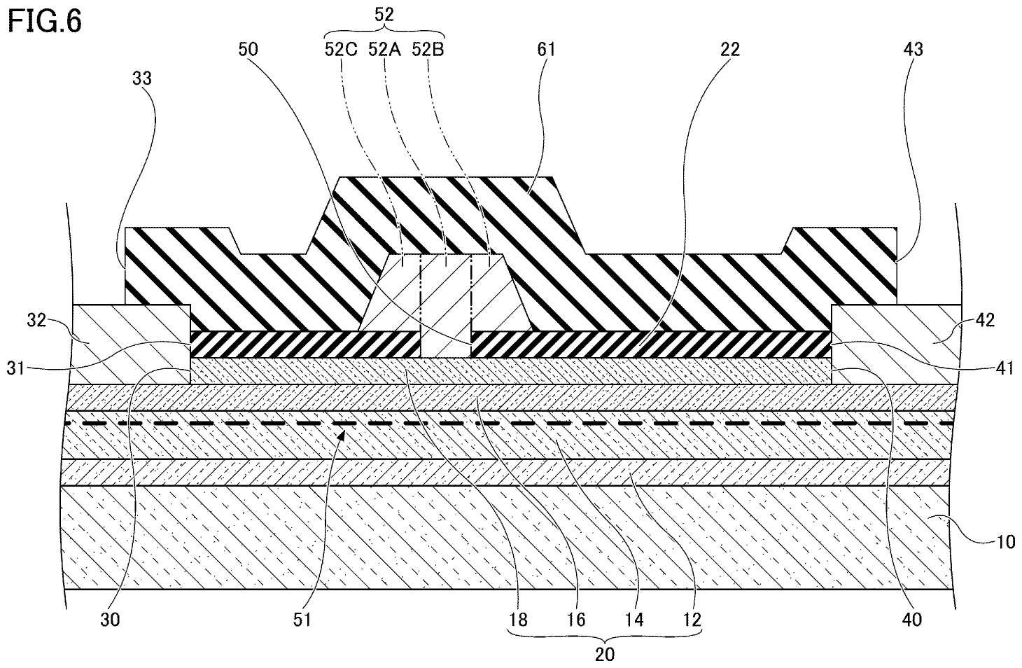

Next, as illustrated in FIG. 6, the openings 33 and 43 are formed in the SiC layer 61. The openings 33 and 43 can be formed by RIE. In the RIE of the SiC layer 61, a fluorine-based material such as sulfur hexafluoride (SF₆) or a chlorine-based material such as chlorine (Cl₂) or boron trichloride (BCl₃) is used as an etching gas, and a noble gas such as Ar is used as a dilution gas.

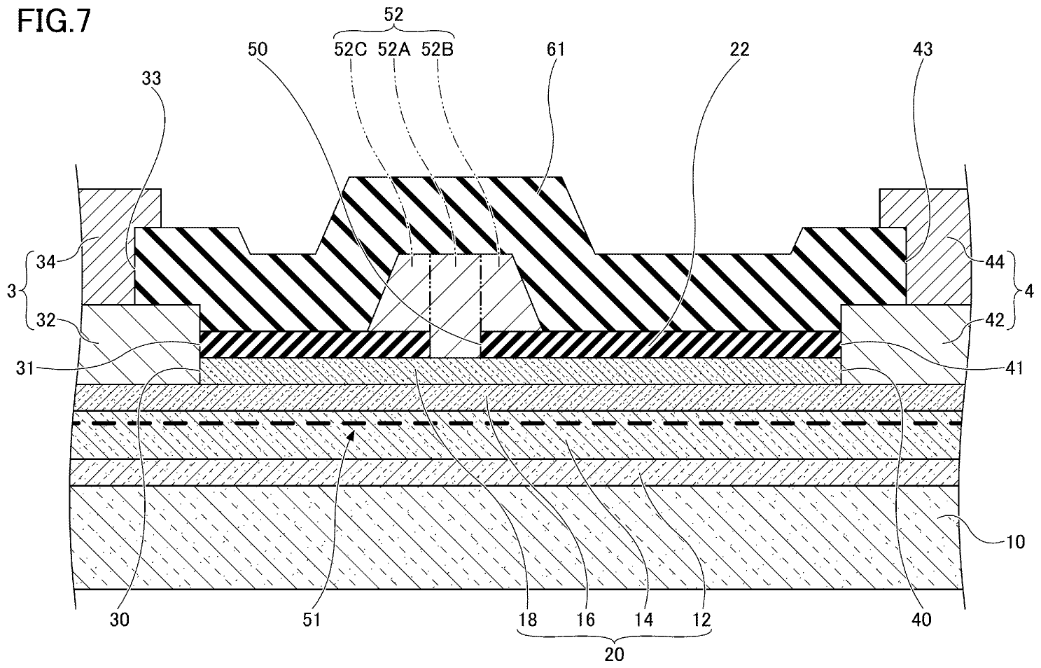

Next, as illustrated in FIG. 7, the source wiring 34 and the drain wiring 44 are formed. The source wiring 34 and the drain wiring 44 can be formed by, for example, a vapor deposition method, a sputtering method, a plating method, an atomic layer deposition (ALD) method, or the CVD method.

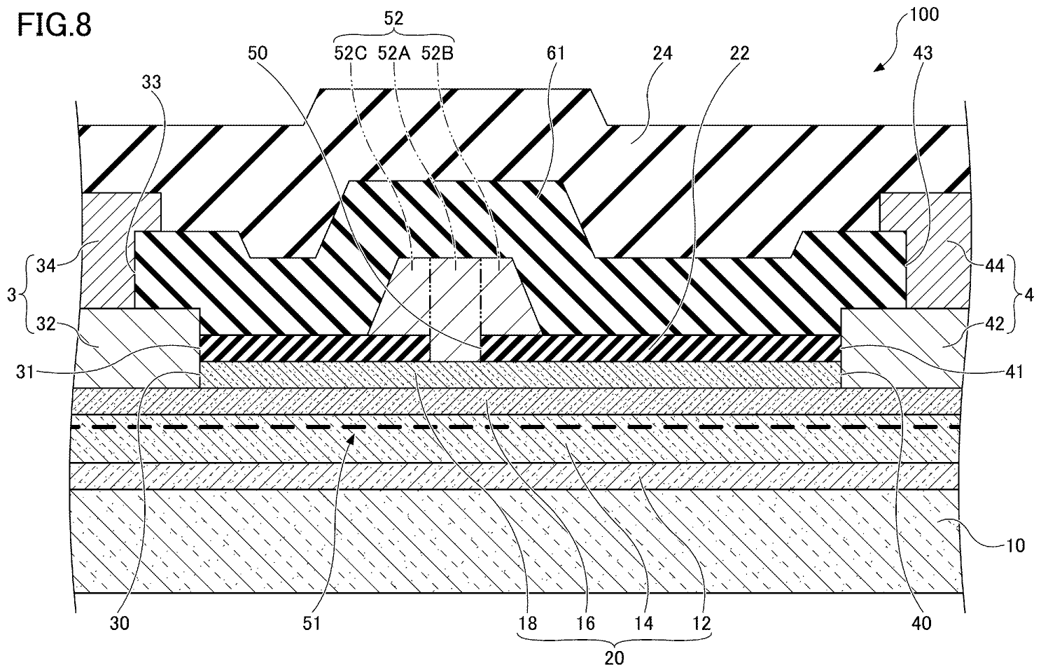

Next, as illustrated in FIG. 8, the passivation film 24 is formed.

In this manner, the semiconductor device 100 according to the first embodiment can be manufactured.

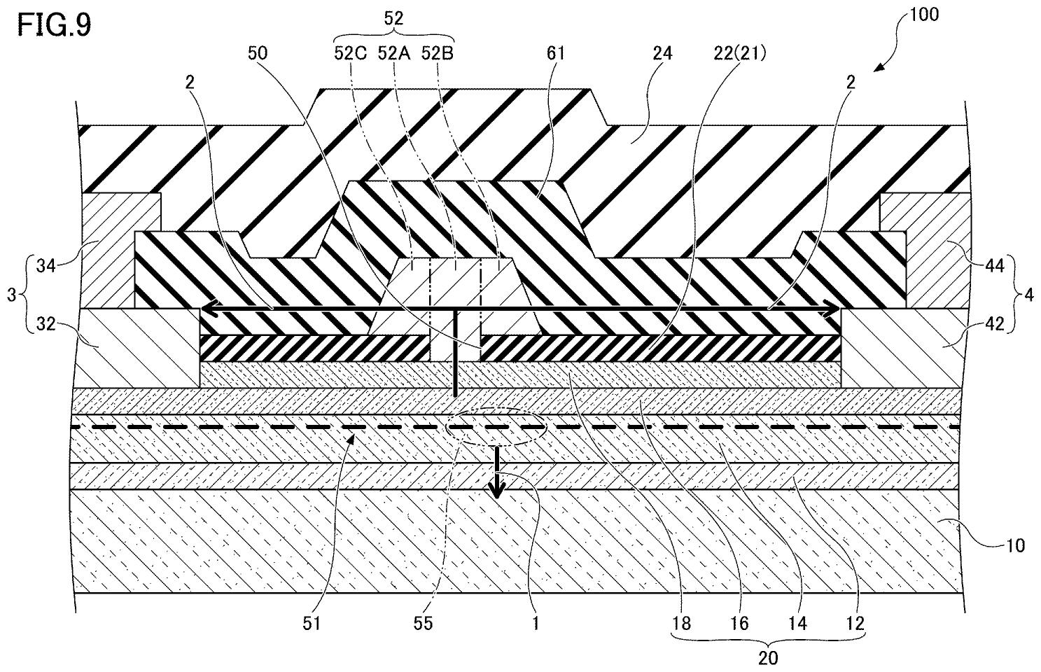

Next, the effects of the semiconductor device 100 according to the first embodiment will be described. FIG. 9 is a cross-sectional view illustrating the effects of the semiconductor device 100 according to the first embodiment.

In the semiconductor device 100, a portion where the 2DEG 51 is present functions as a channel, and heat is easily generated particularly in a region 55 in the vicinity of the first portion 52A. The region 55 is sometimes called a heat spot. In the present embodiment, the heat generated in the region 55 not only diffuses into the substrate 10 (heat dissipation path 1) but also diffuses into the first metal layer 3 and the second metal layer 4 through the gate electrode 52 and the SiC layer 61 (heat radiation path 2). At this time, the heat can be discharged with high efficiency since the thermal resistance of the SiC layer 61 is relatively low. In other words, excellent heat dissipation can be obtained.

The second portion 52B of the gate electrode 52 functions as a field plate. Although the SiN film 22 is present between the second portion 52B and the stacked structure 20, the SiN film 22 can be thin since high thermal conductivity is not required for the SiN film 22. Therefore, electric field concentration in the vicinity of the gate electrode 52 can be sufficiently reduced by the second portion 52B.

As described, according to the present embodiment, heat dissipation can be improved while reducing electric field concentration in the vicinity of the gate electrode 52.

The SiC layer 61 directly contacts the gate electrode 52. Thus, heat is easily transferred from the gate electrode 52 to the SiC layer 61. In addition, the SiC layer 61 directly contacts the first metal layer 3 and the second metal layer 4. Thus, heat is easily transferred from the SiC layer 61 to the first metal layer 3 and the second metal layer 4.

The SiN film 22 is provided on the stacked structure 20. Thus, the surface of the stacked structure 20 is easily protected by the SiN film 22.

The distance between the stacked structure and the second portion 52B is preferably 100 nm or less, more preferably 90 nm or less, and even more preferably 80 nm or less. The smaller this distance is, the easier it is for the second portion 52B to reduce electric field concentration in the vicinity of the gate electrode 52.

The distance between the gate electrode 52 and the first metal layer 3 is preferably 5 μm or less, more preferably 3 μm or less, and even more preferably 1 μm or less. The smaller this distance is, the easier it is to obtain excellent heat dissipation. Similarly, the distance between the gate electrode 52 and the second metal layer 4 is preferably 5 μm or less, more preferably 3 μm or less, and even more preferably 1 μm or less. The smaller this distance is, the easier it is to obtain excellent heat dissipation.

### Second Embodiment

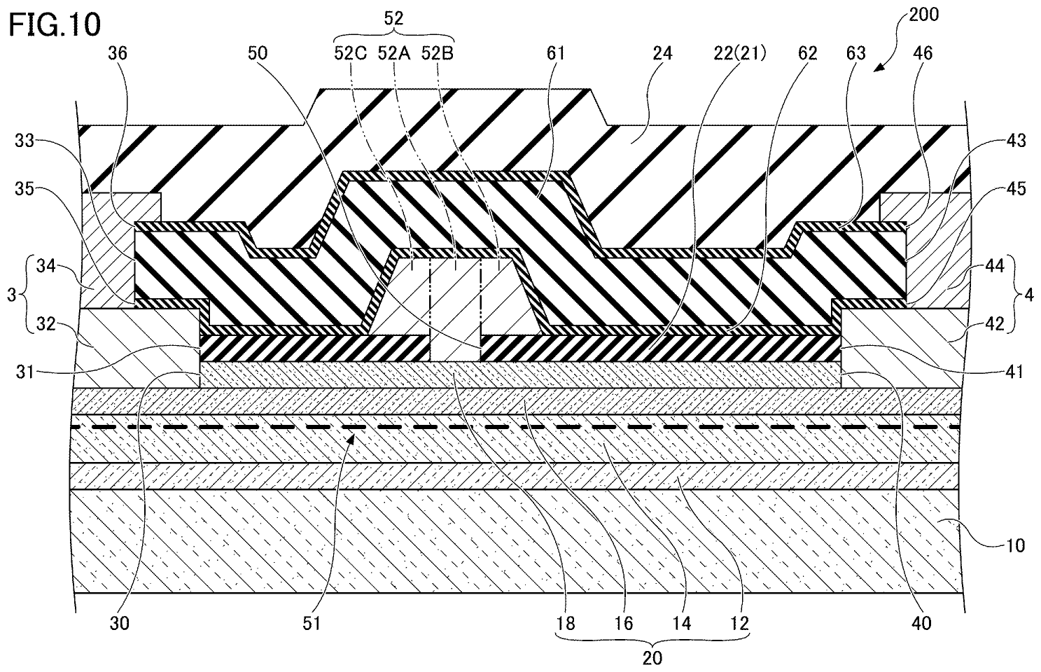

A second embodiment will be described. The second embodiment differs from the first embodiment in that a film for suppressing diffusion of nitrogen into the SiC layer 61 is included. FIG. 10 is a cross-sectional view of a semiconductor device according to the second embodiment.

A semiconductor device 200 according to the second embodiment includes an aluminum oxide (Al₂O₃) film 62 and an Al₂O₃ film 63.

The Al₂O₃ film 62 is provided between the SiN film 22 and the SiC layer 61, and covers the lower surface of the SiC layer 61. The Al₂O₃ film 62 may also be provided between the gate electrode 52 and the SiC layer 61, may also be provided between the source electrode 32 and the SiC layer 61, and may also be provided between the drain electrode 42 and the SiC layer 61. The Al₂O₃ film 62 does not contain nitrogen. Openings 35 and 45 are formed in the Al₂O₃ film 62. The opening 35 leads to the opening 33, and the opening 45 leads to the opening 43. The Al₂O₃ film 62 is an example of a second film.

In the present disclosure, the phrase “does not contain nitrogen” means that the Si—N bond peak is not detected or the Si—N bond peak intensity is 5% or less of the Si—C bond peak intensity in an X-ray photoelectron spectroscopy (XPS) analysis.

The Al₂O₃ film 63 is provided between the SiC layer 61 and the passivation film 24, and covers the upper surface of the SiC layer 61. The Al₂O₃ film 63 does not contain nitrogen. Openings 36 and 46 are formed in the Al₂O₃ film 63. The opening 36 leads to the opening 33, and the opening 46 leads to the opening 43. The Al₂O₃ film 63 is an example of a fourth film. The source wiring 34 is formed in the openings 36, 33, and 35, and the drain wiring 44 is formed in the openings 46, 43, and 45.

Other configurations are the same as those of the first embodiment.

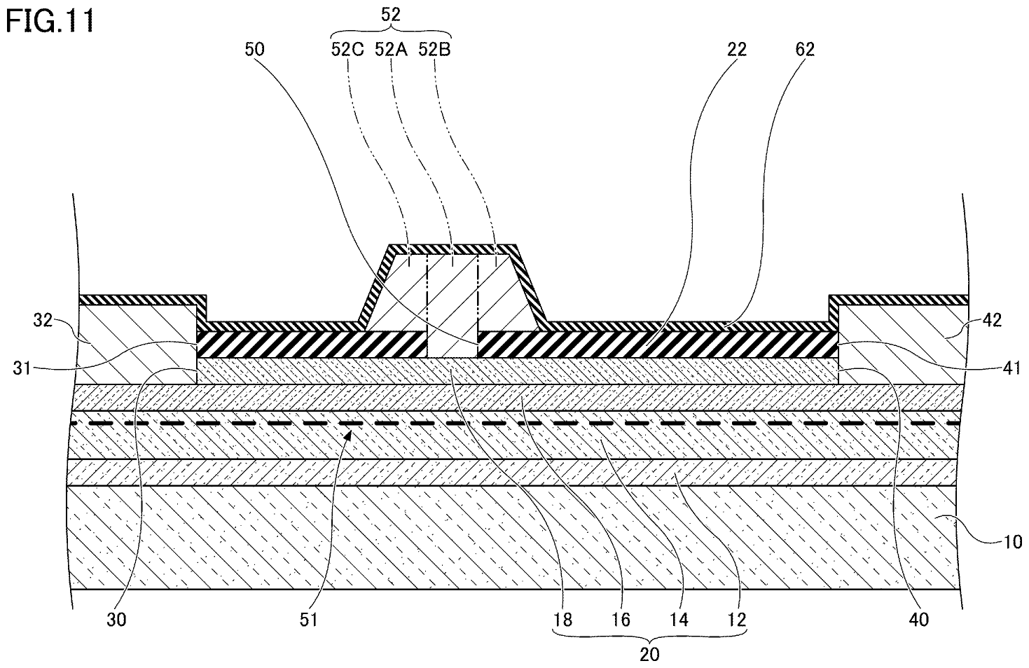

Next, a method of manufacturing the semiconductor device 200 according to the second embodiment will be described. FIG. 11 through FIG. are cross-sectional views illustrating the method of manufacturing the semiconductor device 200 according to the second embodiment.

First, as in the first embodiment, processes up to a process for forming the gate electrode 52 are performed (see FIG. 4). Next, as illustrated in FIG. 11, the Al₂O₃ film 62 is formed so as to cover the gate electrode 52, the SiN film 22, the source electrode 32, and the drain electrode 42. The Al₂O₃ film 62 can be formed by, for example, the ALD method. When the Al₂O₃ film 62 is formed, tetramethylaluminum (TMA) is used as a source gas; oxygen, ozone, or water is used as an oxygen source; and a noble gas such as H₂ or Ar is used as a purge gas. The temperature of the substrate 10 when the Al₂O₃ film 62 is formed is preferably 400° C. or lower in order to suppress changes in the characteristics of the gate electrode 52 due to alloying or the like.

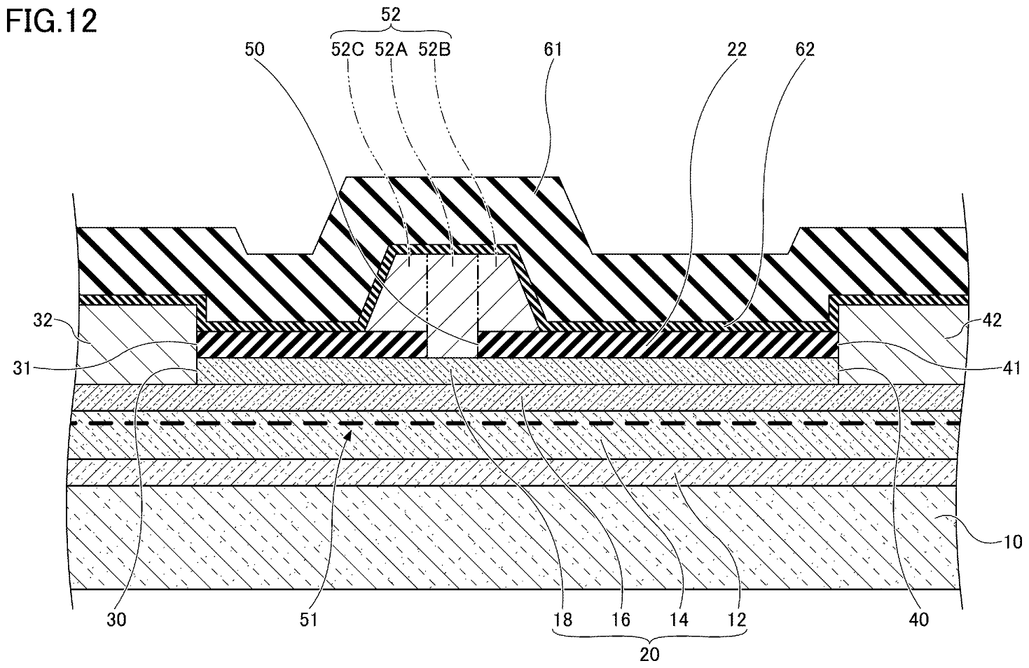

Next, as illustrated in FIG. 12, the SiC layer 61 is formed on the Al₂O₃ film 62. The SiC layer 61 can be formed in the same manner as the first embodiment.

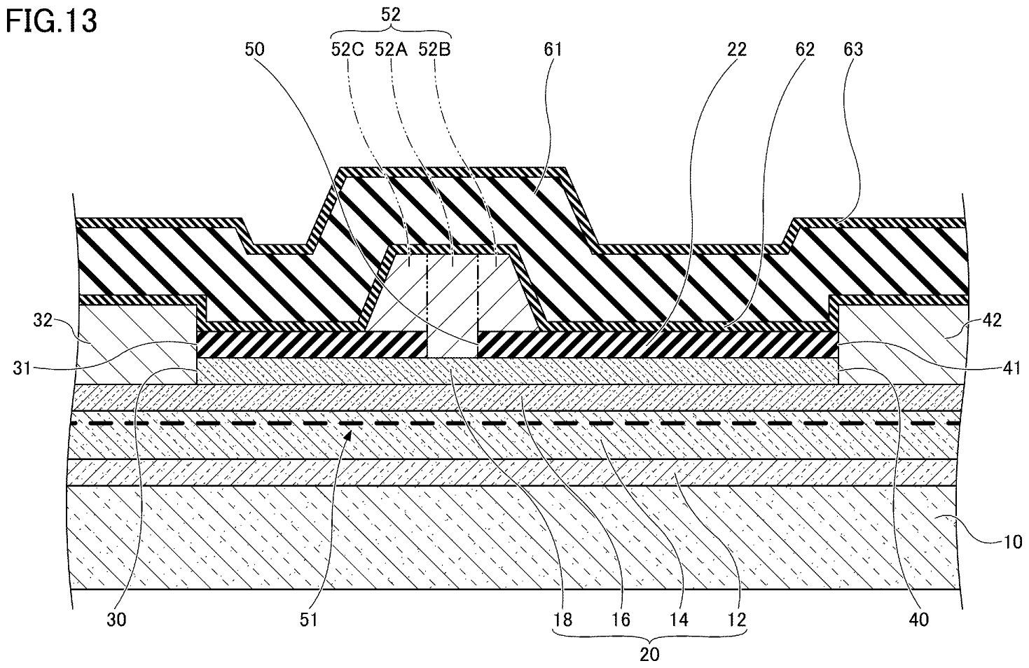

Next, as illustrated in FIG. 13, the Al₂O₃ film 63 is formed on the SiC layer 61. The Al₂O₃ film 63 can be formed in the same manner as the Al₂O₃ film 62.

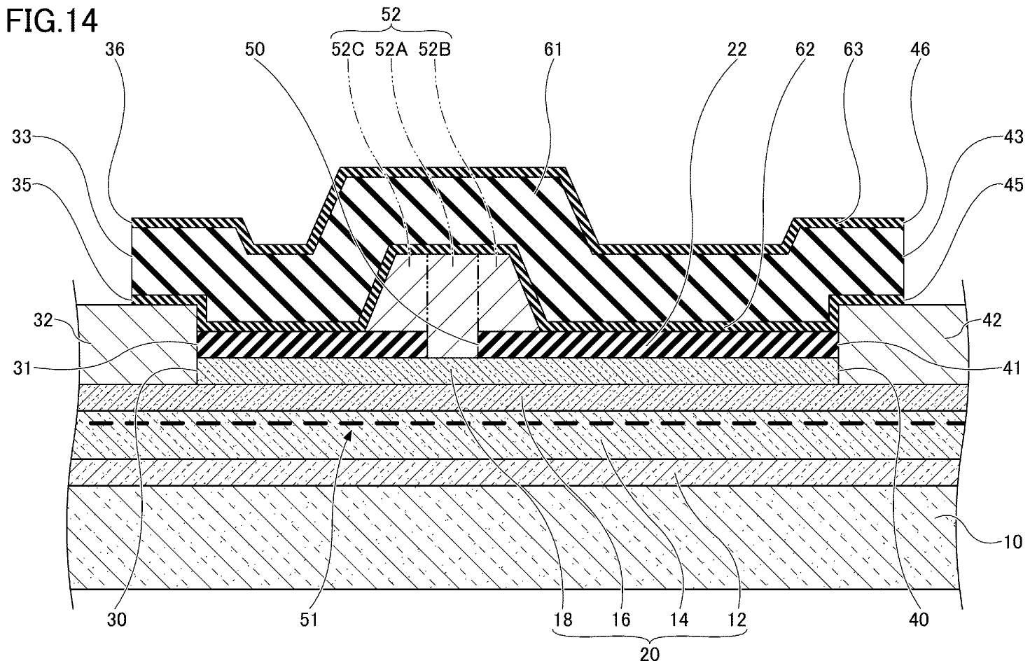

Next, as illustrated in FIG. 14, the openings 36 and 46 are formed in the Al₂O₃ film 63, the openings 33 and 43 are formed in the SiC layer 61, and the openings 35 and 45 are formed in the Al₂O₃ film 62. The openings 36 and 46 can be formed by RIE. In the RIE of the Al₂O₃ film 63, a chlorine-based material such as Cl₂ or BCl₃ is used as an etching gas, and a noble gas such as H₂ or Ar is used as a dilution gas. The openings 33 and 43 can be formed in the same manner as the first embodiment. The openings 35 and 45 can be formed by RIE. In the RIE of the Al₂O₃ film 62, a chlorine-based material such as Cl₂ or BCl₃ is used as an etching gas, and a noble gas such as H₂ or Ar is used as a dilution gas.

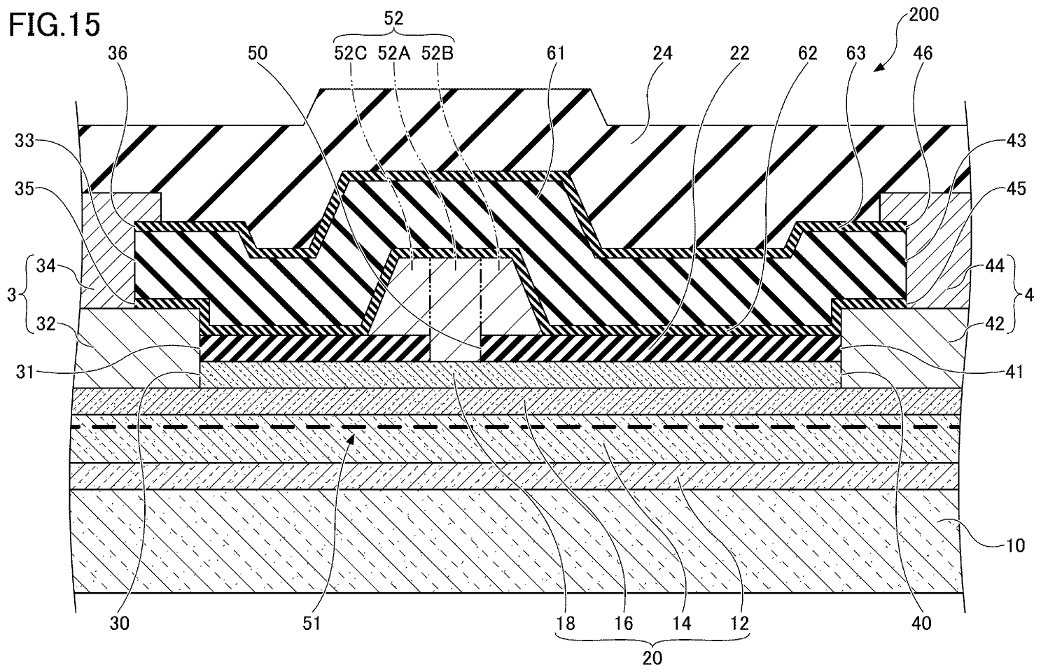

Next, as illustrated in FIG. 15, as in the first embodiment, the source wiring 34 and the drain wiring 44 are formed, and the passivation film 24 is formed.

In this manner, the semiconductor device 200 according to the second embodiment can be manufactured.

The second embodiment can obtain the same effects as those of the first embodiment. In addition, the SiC layer 61 can obtain stable insulating properties. If nitrogen is mixed into the SiC layer 61, there may be a possibility that the SiC layer 61 may have an n-conductive type. In the present embodiment, the Al₂O₃ film 62 is provided between the SiC layer 61 and the SiN film 22, and the Al₂O₃ film 63 is provided between the SiC layer 61 and the passivation film 24. Therefore, diffusion of nitrogen from the SiN film 22 or the passivation film 24 into the SiC layer 61 can be suppressed, and the SiC layer 61 can obtain stable insulating properties.

A silicon oxide (SiO₂) film may be used instead of the Al₂O₃ film 62, and a SiO₂ film may be used instead of the Al₂O₃ film 63. The SiO₂ films can be formed by, for example, the ALD method or the plasma CVD method. When the SiO₂ films are formed by the plasma CVD method, for example, silane (SiH₄) or tetraethoxysilane (TEOS) is used as a source gas, oxygen is used as an oxygen source, and a noble gas such as H₂ or Ar is used as a dilution gas. The temperature of the substrate 10 when the SiO₂ films are formed is preferably 400° C. or lower. Note that it is preferable not to use a substance including nitrogen such as nitrous oxide (N₂O). When openings are formed in the SiO₂ films by RIE, a fluorine-based gas such as SF₆ or CₓF_{y}H_{z} is used for example. In embodiments as will be described later, a SiO₂ film may be used instead of an Al₂O₃ film.

The chemical stability of Al—O bonds constituting the Al₂O₃ film and the chemical stability Si—O bonds constituting the SiO₂ film are high. Therefore, diffusion of nitrogen is easily suppressed by the Al₂O₃ film or the SiO₂ film.

The Al₂O₃ film 62 does not necessarily cover the gate electrode 52, and the SiC layer 61 may directly contact the gate electrode 52. Further, one of the Al₂O₃ film 62 and the Al₂O₃ film 63 does not need to be provided.

### Third Embodiment

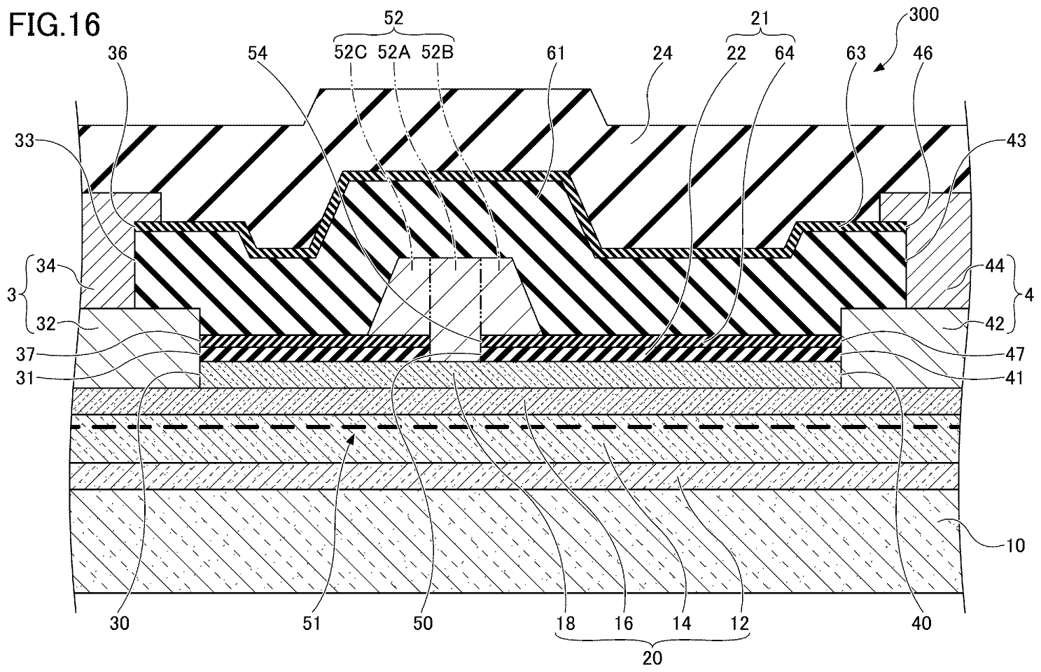

A third embodiment will be described. The third embodiment differs from the second embodiment mainly in the configuration of the first film 21. FIG. 16 is a cross-sectional view of a semiconductor device according to the third embodiment.

A semiconductor device 300 according to the third embodiment includes a diamond film 64 and an Al₂O₃ film 63. As in the second embodiment, the Al₂O₃ film 63 is provided between the SiC layer 61 and the passivation film 24, and covers the upper surface of the SiC layer 61.

The diamond film 64 is provided on the SiN film 22. An opening 37 leading to the opening 31, an opening 47 leading to the opening 41, and an opening 54 leading to the opening 50 are formed in the diamond film 64. The first portion 52A of the gate electrode 52 directly contacts the capping layer 18 through the openings 54 and 50. The second portion 52B is connected to the first portion 52A, is disposed on the diamond film 64, and is located closer to the drain electrode 42 than the first portion 52A is. The third portion 52C is connected to the first portion 52A, is disposed on the diamond film 64, and is located closer to the source electrode 32 than the first portion 52A is. The source electrode 32 is formed in the openings 30, 31, and 37, and the drain electrode 42 is formed in the openings 40, 41, and 47. In the present embodiment, the first film 21 includes the SiN film 22 and the diamond film 64. The SiC layer 61 is formed on the diamond film 64.

Other configurations are the same as those of the second embodiment.

The third embodiment can obtain the same effects as those of the first embodiment. In addition, the diamond film 64 is provided between the SiC layer 61 and the SiN film 22. Therefore, diffusion of nitrogen from the SiN film 22 into the SiC layer 61 can be suppressed, and the SiC layer 61 can obtain stable insulating properties. Further, the diamond film 64 has excellent thermal conductivity, and thus, better heat dissipation can be obtained.

The thickness of the first film 21 is preferably 100 nm or less, more preferably 90 nm or less, and even more preferably 80 nm or less. The smaller the thickness of the first film 21 is, the easier it is for the second portion 52B to reduce electric field concentration in the vicinity of the gate electrode 52.

Instead of the diamond film 64, an Al₂O₃ film, a SiO₂ film, or a diamond-like carbon film may be used. Further, in embodiments as will be described later, instead of a diamond film, an Al₂O₃ film, a SiO₂ film, or a diamond-like carbon film may be used.

The chemical stability of C—C bonds constituting the diamond-like carbon film is high. Further, as described above, the chemical stability of Al—O bonds constituting the Al₂O₃ film and the chemical stability of Si—O bonds constituting the SiO₂ film are high. Therefore, diffusion of nitrogen is easily suppressed by the Al₂O₃ film, the SiO₂ film, the diamond film, or the diamond-like carbon film.

### Fourth Embodiment

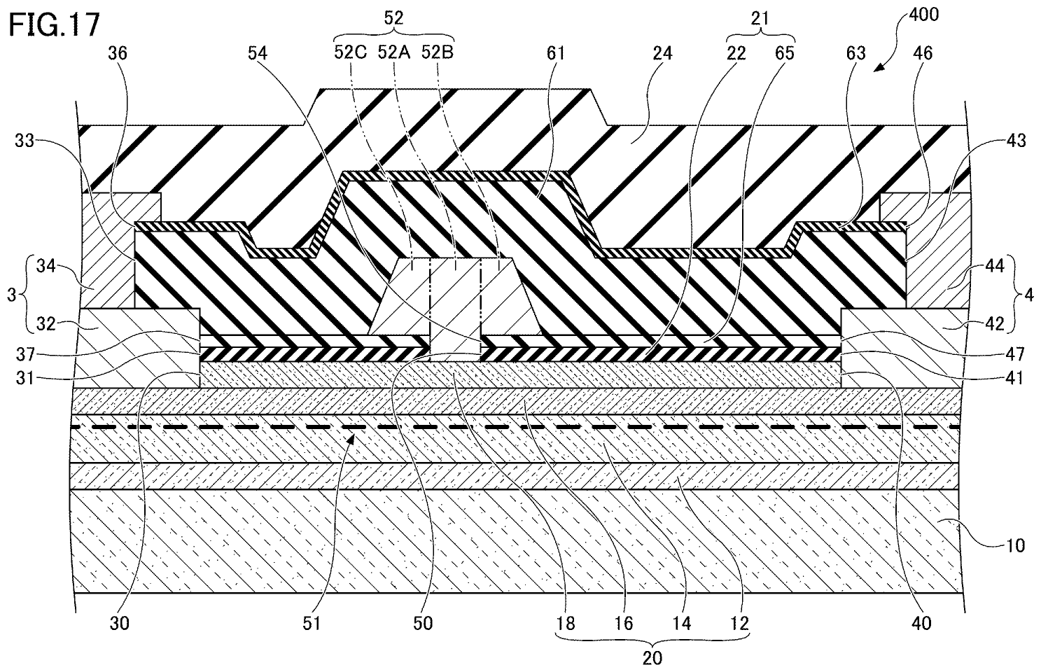

A fourth embodiment will be described. The fourth embodiment differs from the third embodiment mainly in the configuration of the first film 21. FIG. 17 is a cross-sectional view of a semiconductor device according to the fourth embodiment.

A semiconductor device 400 according to the fourth embodiment includes a SiC film 65 instead of the diamond film 64. As with the case of the diamond film 64, the openings 54, 37, and 47 are formed in the SiC film 65. In the present embodiment, the first film 21 includes the SiN film 22 and the SiC film 65.

Other configurations are the same as those of the third embodiment.

The fourth embodiment can obtain the same effects as those of the first embodiment. In addition, the Al₂O₃ film 63 is provided between the SiC layer 61 and the passivation film 24.

Therefore, diffusion of nitrogen from the passivation film 24 into the SiC layer 61 can be suppressed, and the SiC layer 61 can obtain stable insulating properties.

### Fifth Embodiment

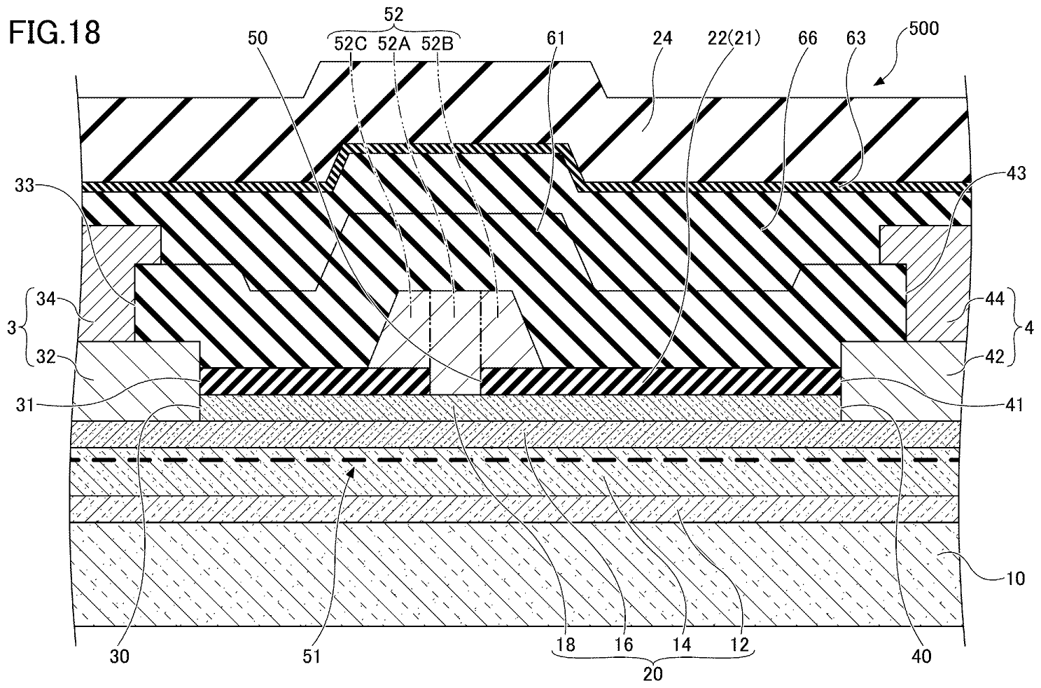

A fifth embodiment will be described. The fifth embodiment differs from the first embodiment mainly in the configuration above the SiC layer 61. FIG. 18 is a cross-sectional view of a semiconductor device according to the fifth embodiment.

A semiconductor device 500 according to the fifth embodiment includes a SiC layer 66 and an Al₂O₃ film 63. The SiC layer 66 covers the source wiring 34, the drain wiring 44, and the SiC layer 61. The Al₂O₃ film 63 is provided between the SiC layer 66 and the passivation film 24, and covers the upper surface of the SiC layer 66.

Other configurations are the same as those of the first embodiment.

The fifth embodiment can obtain the same effects as those of the first embodiment. In addition, the Al₂O₃ film 63 is provided between the passivation film 24 and the SiC layers 61 and 66.

Therefore, diffusion of nitrogen from the passivation film 24 into the SiC layers 61 and 66 can be suppressed, and the SiC layers 61 and 66 can obtain stable insulating properties.

### Sixth Embodiment

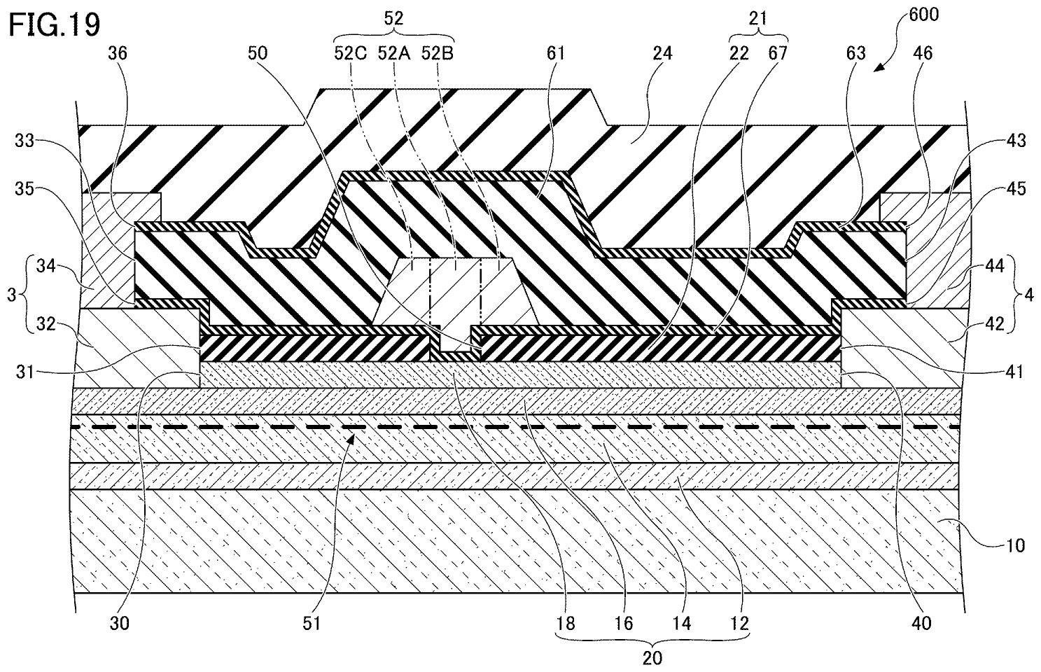

A sixth embodiment will be described. The sixth embodiment differs from the second embodiment mainly in that an insulating film is present between the gate electrode 52 and the capping layer 18. FIG. 19 is a cross-sectional view of a semiconductor device according to the sixth embodiment.

A semiconductor device 600 according to the sixth embodiment does not include the Al₂O₃ film 62, but includes an Al₂O₃ film 67. The Al₂O₃ film 67 is provided on the SiN film 22, the source electrode 32, and the drain electrode 42. The Al₂O₃ film 67 covers the inner wall surface of the opening 50 and the surface of the capping layer 18 exposed from the opening 50. As with the case of the Al₂O₃ film 62, the openings 35 and 45 are formed in the Al₂O₃ film 67. The first film 21 includes the SiN film 22 and the Al₂O₃ film 67.

The gate electrode 52 is provided on the Al₂O₃ film 67. The first portion 52A is located within the opening 50 in a plan view. The second portion 52B is connected to the first portion 52A, is disposed on the Al₂O₃ film 67, and is located closer to the drain electrode 42 than the first portion 52A is. The third portion 52C is connected to the first portion 52A, is disposed on the Al₂O₃ film 67, and is located closer to the source electrode 32 than the first portion 52A is. The 13 Al₂O₃ film 67 is present between the first portion 52A and the capping layer 18.

Other configurations are the same as those of the second embodiment.

The sixth embodiment can obtain the same effects as those of the second embodiment.

### Seventh Embodiment

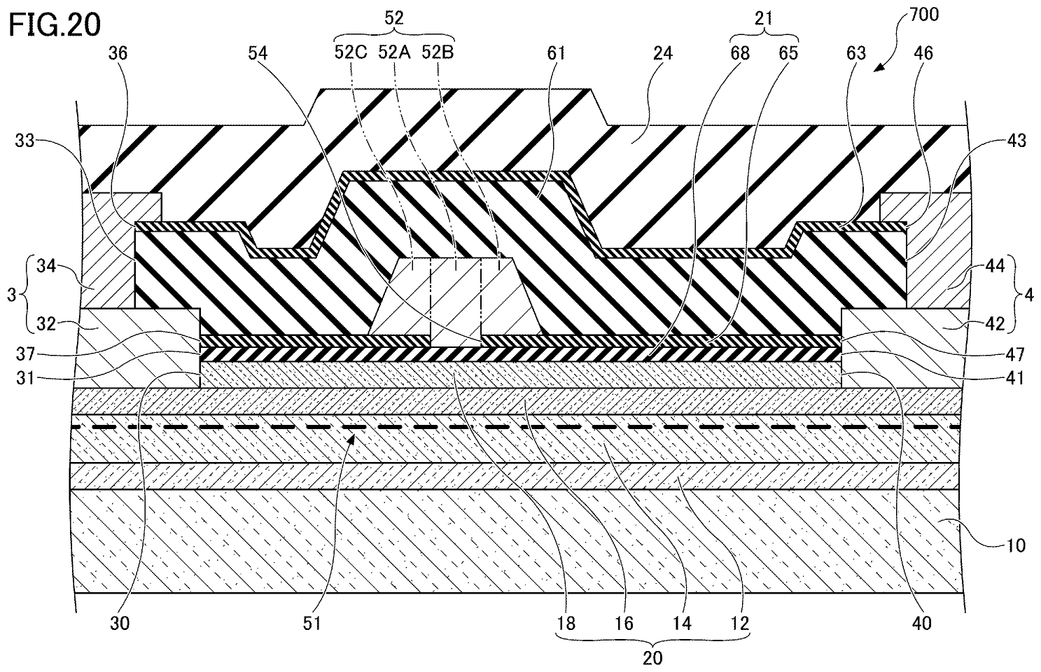

A seventh embodiment will be described. The seventh embodiment differs from the fourth embodiment mainly in the configuration of the first film 21. FIG. 20 is a cross-sectional view of a semiconductor device according to the seventh embodiment.

A semiconductor device 700 according to the seventh embodiment includes an Al₂O₃ film 68 instead of the SiN film 22. As with the case of the SiN film 22, the openings 31 and 41 are formed in the Al₂O₃ film 68, but the opening 50 is not formed in the Al₂O₃ film 68. In the present embodiment, the first film 21 includes the Al₂O₃ film 68 and the SiC film 65.

The gate electrode 52 is provided on the Al₂O₃ film 68 and the SiC film 65. The first portion 52A is located within the opening 54 in a plan view. The second portion 52B is connected to the first portion 52A, is disposed on the SiC film 65, and is located closer to the drain electrode 42 than the first portion 52A is. The third portion 52C is connected to the first portion 52A, is disposed on the SiC film 65, and is located closer to the source electrode 32 than the first portion 52A is. The Al₂O₃ film 68 is present between the first portion 52A and the capping layer 18.

Other configurations are the same as those of the fourth embodiment.

The seventh embodiment can obtain the same effects as those of the fourth embodiment.

Instead of the Al₂O₃ film 68, a silicon oxide film may be used.

### Eighth Embodiment

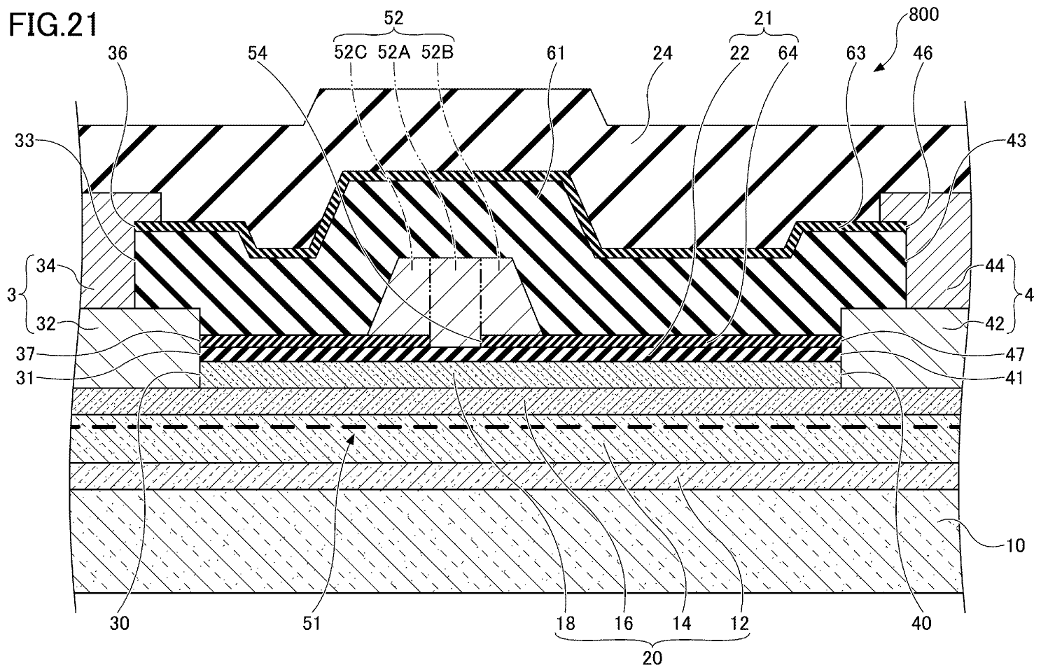

An eighth embodiment will be described. The eighth embodiment differs from the third embodiment mainly in the configuration of the first film 21. FIG. 21 is a cross-sectional view of a semiconductor device according to the eighth embodiment.

In a semiconductor device 800 according to the eighth embodiment, the opening 50 is not formed in the SiN film 22. The gate electrode 52 is provided on the SiN film 22 and the diamond film 64. The first portion 52A is located within the opening 54 in a plan view. The second portion 52B is connected to the first portion 52A, is disposed on the diamond film 64, and is located closer to the drain electrode 42 than the first portion 52A is. The third portion 52C is connected to the first portion 52A, is disposed on the diamond film 64, and is located closer to the source electrode 32 than the first portion 52A is. The SiN film 22 is present between the first portion 52A and the capping layer 18.

Other configurations are the same as those of the third embodiment.

The eighth embodiment can obtain the same effects as those of the third embodiment.

The configuration of the semiconductor layers included in the stacked structure 20 is not limited to the configurations according to the above-described embodiments. For example, in the sixth embodiment, the seventh embodiment, and the eighth embodiment, the electron supply layer 16 may be provided between the substrate 10 and the electron transit layer 14. That is, in the sixth embodiment, the seventh embodiment, and the eighth embodiment, what is known as an inverted HEMT structure may be employed.

Although the embodiments have been described in detail above, the present disclosure is not limited to a specific embodiment, and various modifications and alterations can be made within the scope described in the claims.

What is claimed is:

1. A semiconductor device comprising:
a substrate;
a semiconductor layer provided on the substrate;
a source electrode and a drain electrode, the source electrode and the drain electrode being provided on the semiconductor layer;
a first film including a first insulating film that is provided on the semiconductor layer and is located between the source electrode and the drain electrode;
a gate electrode provided between the source electrode and the drain electrode; and
a silicon carbide layer covering the gate electrode,
wherein the first film has an opening, and
wherein the gate electrode includes
a first portion that is located within the opening in a plan view, and
a second portion that is connected to the first portion, is disposed on the first film, and is located closer to the drain electrode than the first portion is.

2. The semiconductor device according to claim 1, further comprising a second film that is provided between the first film and the silicon carbide layer, covers a lower surface of the silicon carbide layer, and does not contain nitrogen.

3. The semiconductor device according to claim 2, wherein the second film is an aluminum oxide film or a silicon oxide film.

4. The semiconductor device according to claim 1, wherein the first film includes a third film that is provided between the first insulating film and the silicon carbide layer, covers a lower surface of the silicon carbide layer, and does not contain nitrogen.

5. The semiconductor device according to claim 4, wherein the third film is an aluminum oxide film, a silicon oxide film, a diamond film, or a diamond-like carbon film.

6. The semiconductor device according to claim 1, wherein the first insulating film is a silicon nitride film.

7. The semiconductor device according to claim 1, further comprising a fourth film that covers an upper surface of the silicon carbide layer and does not contain nitrogen.

8. The semiconductor device according to claim 7, wherein the fourth film is an aluminum oxide film or a silicon oxide film.

9. The semiconductor device according to claim 1, wherein the silicon carbide layer directly contacts the gate electrode.

10. The semiconductor device according to claim 1, further comprising:
a first metal layer including the source electrode; and
a second metal layer including the drain electrode,
wherein the silicon carbide layer directly contacts at least one of the first metal layer or the second metal layer.

11. The semiconductor device according to claim 10, wherein a distance between the gate electrode and the first metal layer is 5 μm or less, and a distance between the gate electrode and the second metal layer is 5 μm or less.

12. The semiconductor device according to claim 1, wherein a distance between the semiconductor layer and the second portion is 100 nm or less.

13. A semiconductor device comprising:
a substrate;
a semiconductor layer provided on the substrate;
a source electrode and a drain electrode, the source electrode and the drain electrode being provided on the semiconductor layer;
a first film including a silicon nitride film that is provided on the semiconductor layer and is located between the source electrode and the drain electrode;
a gate electrode provided between the source electrode and the drain electrode;
a silicon carbide layer covering the gate electrode;
a second film that is provided between the first film and the silicon carbide layer, covers a lower surface of the silicon carbide layer, and does not contain nitrogen;
a first metal layer including the source electrode; and
a second metal layer including the drain electrode,
wherein the first film has an opening,
wherein the gate electrode includes
a first portion that is located within the opening in a plan view, and
a second portion that is connected to the first portion, is disposed on the first film, and is located closer to the drain electrode than the first portion is,
wherein the second film is an aluminum oxide film or a silicon oxide film,
wherein the silicon carbide layer directly contacts at least one of the first metal layer or the second metal layer, and
wherein a distance between the semiconductor layer and the second portion is 100 nm or less.

14. A method of manufacturing a semiconductor device, the method comprising:
forming a semiconductor layer on a substrate;
forming a source electrode and a drain electrode on the semiconductor layer;
forming a first film including a first insulating film on the semiconductor layer and between the source electrode and the drain electrode;
forming an opening in the first film;
forming a gate electrode including a first portion and a second portion, the first portion being located within the opening in a plan view, and the second portion being disposed on the first film and being located closer to the drain electrode than the first portion is; and
forming a silicon carbide layer so as to cover the gate electrode.
